(19) United States
(12) Patent Application Publication
(10) Pub. No.: US 2025/0336722 A1
(43) Pub. Date: Oct. 30, 2025

(54) FLUX GRADIENT MOLYBDENUM GROWTH PROCESS

(71) Applicant: Applied Materials, Inc., Santa Clara, CA (US)

(72) Inventors: Wei LEI, Santa Clara, CA (US); Sahil Jaykumar PATEL, Sunnyvale, CA (US); Shiyu YUE, Santa Clara, CA (US); Zhimin QI, Santa Clara, CA (US); Ju Hyun OH, San Jose, CA (US)

(21) Appl. No.: 18/645,741

(22) Filed: Apr. 25, 2024

(51) Int. Cl. H01L 21/768; H01L 21/3205

(52) U.S. Cl. CPC H01L 21/76876; H01L 21/32051; H01L 21/76877

(57) ABSTRACT

The present disclosure provides methods for processing a semiconductor device substrate. A nucleation layer is deposited on a surface of a feature formed in a surface of a substrate by a first deposition process. The first deposition process including flowing a molybdenum-containing precursor and a reducing agent precursor gas into a processing chamber at a first flow rate ratio of about 1×10⁻⁸ to about 2×10⁻³ of molybdenum-containing precursor to reducing agent. At least a portion of the feature is filled with a molybdenum gap fill material by exposing the deposited nucleation layer feature to a second deposition process. The second deposition process including flowing the molybdenum-containing precursor and the reducing agent precursor gas into a processing chamber at a second flow rate ratio of about 2×10⁻⁵ to about 1×10⁻² of molybdenum-containing precursor to reducing agent, wherein the second flow rate ratio is greater than the first flow rate ratio.

### BACKGROUND

### Field

The present disclosure generally relates to a method and apparatus for forming thin-films. More particularly, the disclosure relates to a method and apparatus for molybdenum fill in semiconductor devices.

### Description of the Related Art

The fabrication of microelectronic devices typically involves a complicated process sequence requiring hundreds of individual processes performed on semi-conductive, dielectric and conductive substrates. Examples of these processes include oxidation, diffusion, ion implantation, thin film deposition, cleaning, etching, lithography among other operations. Each of these processes become more complex with increasing aspect ratios of features formed in a surface of a substrate.

Conventionally, high aspect ratios of features of a substrate can be filled with precursor materials that form a gap fill material within the feature. For example, one such precursor material can include a molybdenum-based precursors. Unfortunately, molybdenum-based precursors may concurrently etch and deposit the gap fill material, thereby hindering nucleation of the molybdenum-based gap fill material. Moreover, the byproduct of the etched gap fill material with the molybdenum-based precursor can be retained in the gap fill material, thereby reducing density of the gap fill material and device efficiency.

Accordingly, there is a need for improved fabrication methods.

### SUMMARY

In some embodiments, the present disclosure provides methods for processing a semiconductor device substrate. A nucleation layer is deposited on a surface of a feature formed in a surface of a substrate by a first deposition process. The first deposition process including flowing a molybdenum-containing precursor and a reducing agent precursor gas into a processing chamber at a first flow rate ratio of about 1×10⁻⁸ to about 2×10⁻³ of molybdenum-containing precursor to reducing agent. At least a portion of the feature is filled with a molybdenum gap fill material by exposing the deposited nucleation layer feature to a second deposition process. The second deposition process including flowing the molybdenum-containing precursor and the reducing agent precursor gas into a processing chamber at a second flow rate ratio of about 2×10⁻⁵ to about 1×10⁻² of molybdenum-containing precursor to reducing agent, wherein the second flow rate ratio is greater than the first flow rate ratio.

In other embodiments, the present disclosure provides methods for processing a semiconductor device substrate. A grain layer including tungsten is deposited over at least a portion of a feature formed in a surface of a substrate by use of a physical vapor deposition (PVD) process. The PVD process is performed in a first processing region of a first processing chamber. The substrate is transferred from the first processing region of the first processing chamber to a second processing region of a second processing chamber without breaking vacuum. A nucleation layer is deposited on the grain layer by exposing the feature to a first deposition process. The first deposition process including flowing a molybdenum-containing precursor and a reducing agent precursor gas into a processing chamber at a first flow rate ratio of about 1×10⁻⁸ to about 2−10⁻³ of molybdenum-containing precursor to reducing agent. The feature is filled with a molybdenum gap fill material by exposing the feature to a second deposition process. The second deposition process including flowing the molybdenum-containing precursor and the reducing agent precursor gas into a processing chamber at a second flow rate ratio of about 2×10⁻⁵ to about 1×10⁻² of molybdenum-containing precursor to reducing agent. The second flow rate ratio is greater than the first flow rate ratio

In other embodiments, the present disclosure provides methods for processing a semiconductor device substrate. A nucleation layer is deposited on a surface of a feature formed in a surface of a substrate by use of a first deposition process. The first deposition process including flowing a molybdenum-containing precursor into a processing chamber at a first flow rate. At least a portion of the feature is filled with a molybdenum gap fill material by exposing the deposited nucleation layer feature to a second deposition process. The second deposition process including flowing the molybdenum-containing precursor at a second flow rate. A ratio of the first flow rate to the second flow rate is from about 2×10⁻⁵ to about 1×10⁻² of molybdenum-containing precursor to reducing agent.

### BRIEF DESCRIPTION OF THE DRAWINGS

So that the manner in which the above-recited features of the present disclosure can be understood in detail, a more particular description of the aspects, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a top view schematic illustrating a top view of a multi-chamber processing tool, in accordance with embodiments of the present disclosure.

FIG. 2 is a flow diagram illustrating a method for manufacturing a device, in accordance with embodiments of the present disclosure.

FIGS. 3A-3E are cross-sectional views of a device based on the method of FIG. 2, in accordance with embodiments of the present disclosure.

FIG. 4 is a chart illustrating a deposition rate of molybdenum when using a low flux or a high flux, in accordance with embodiments of the present disclosure.

FIG. 5 is a chart illustrating a device filled with a molybdenum gap fill material when using a first deposition process or a second deposition process, in accordance with embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to methods and apparatus for forming thin-films. More particularly, the disclosure relates to methods and apparatus for molybdenum fill of semiconductor devices. The first deposition process can reduce an incubation delay for forming the nucleation layer due to the lower flux utilized compared to conventional deposition processes. Moreover, the first deposition process can reduce the total amount of etching of the gap fill material due to the lower flux compared to conventional deposition processes, thereby reducing byproducts from forming in the nucleation layer and/or the gap fill material. Additionally, the second deposition process, having a higher flux compared to the first deposition process, can reduce the total manufacturing time without reducing the ability to completely fill the features formed in a substrate, thereby reducing manufacturing costs.

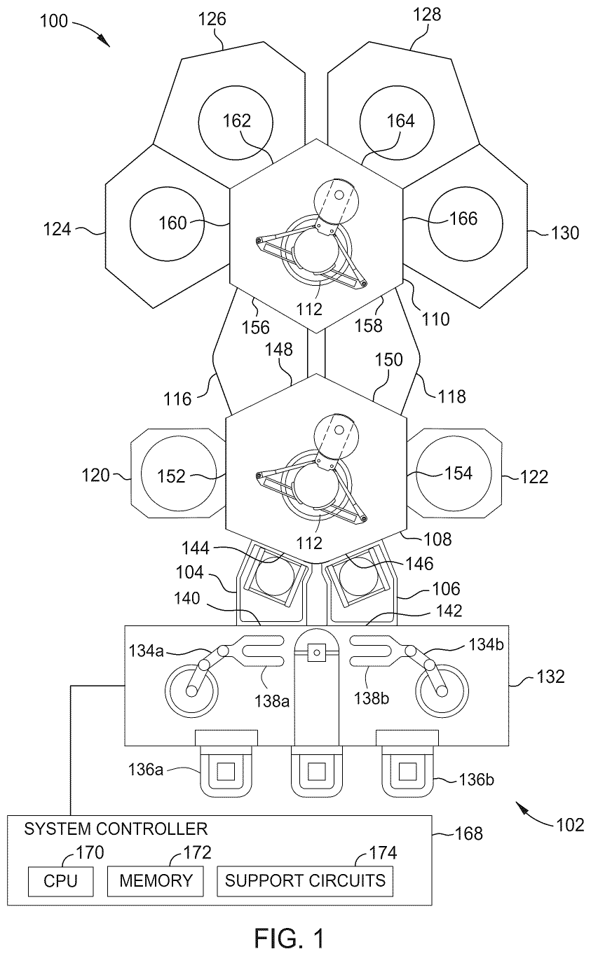

FIG. 1 illustrates a schematic top view of a multi-chamber processing system 100 in accordance with one or more embodiments of the present disclosure. The processing system 100 can be used for deposition of a nucleation layer followed by seamless gap-fill of molybdenum without breaking vacuum in accordance with one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100, for example, an atmospheric ambient environment such as may be present in a fab. The substrates can be processed in and transferred between the various chambers maintained at a low pressure, for example, less than or equal to about 300 Torr, or a vacuum environment without breaking the low pressure or vacuum environment among various processes performed on the substrates in the processing system 100. Accordingly, the processing system 100 may provide for an integrated solution for processing of substrates.

Examples of processing systems that may be suitably modified in accordance with the teachings provided herein include the Endura®, Producer®, Centris® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134a-b to facilitate transfer of substrates. The docking station 132 is adapted to accept one or more front opening unified pods (FOUPs) 136a-b. In some examples, each factory interface robot 134a-b generally includes a blade 138a-b disposed on one end of the respective factory interface robot 134a-b adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, the transfer chambers 108, 110, the holding chambers 116, 118, and the processing chambers 120, 122, 124, 126, 128, 130 may be fluidly coupled to a gas and pressure control system (not specifically illustrated). The gas and pressure control system can include one or more gas pumps (for example, turbo pumps, cryo-pumps, roughing pumps) gas sources, various valves, and conduits fluidly coupled to the various chambers. In operation, the factory interface robot 134a-b transfers a substrate from the FOUP 136a-b through the port 140 or 142 to the load lock chamber 104 or 106. The gas and pressure control system then pumps down the load lock chamber 104 or 106. The gas and pressure control system further maintains the transfer chambers 108, 110 and the holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, and the processing chambers 126, 128, 130 can be capable of performing respective growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Centura™ Epi chamber, Volta™ CVD/ALD chamber, Forza™ quad pedestal, Premus™ quad pedestal, or Encore™ PVD chambers available from Applied Materials of Santa Clara, Calif.

A system controller 168 is coupled to the processing system 100 for controlling the processing system 100 or components thereof. For example, the system controller 168 may control the operation of the processing system 100 using a direct control of the processing chambers 104, 106, 108, 110, 116, 118, 120, 122, 124, 126, 128, 130 of the processing system 100 or by controlling controllers associated with the processing chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general-purpose processor that can be used in an industrial setting. The memory 172, non-transitory computer-readable medium, or machine-readable storage device, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. That is, the computer program product is tangibly embodied on the memory 172 (or non-transitory computer-readable medium or machine-readable storage device). When the computer instruction code is executed by the CPU 170, the CPU 170 controls the chambers to perform processes in accordance with the various methods.

The instructions in memory 172 may be in the form of a program product, such as a program that implements the methods of the present disclosure. In one example, the disclosure may be implemented as a program product stored on a computer-readable storage media for use with a computer system. The program(s) of the program product define functions of the embodiments (including the methods described herein). Thus, the computer-readable storage media, when carrying computer-readable instructions that direct the functions of the methods described herein, are embodiments of the present disclosure. The system controller 168 is configured to perform methods such as the method 200 stored in the memory 172.

In some embodiments, at least one of the processing chambers 120 and 122 is a pre-clean chamber configured to perform a pretreatment process. In some embodiments, at least one of the processing chambers 124, 126, 128, 130 is a PVD chamber configured to perform the PVD tungsten deposition process of operation 220 of the method 200. In some embodiments, at least one of the processing chambers 124, 126, 128, 130 is a CVD chamber configured to perform a molybdenum deposition process of operation 230 and/or 240 of the method 200 without breaking vacuum between any of the operations 210-250.

In operation, a substrate having a feature formed therein may be transferred to a first processing chamber which is one of the processing chambers 122 and 124 where the feature is exposed to a pretreatment process to remove, for example, native oxides formed on the feature. The substrate may then be transferred to a second processing chamber which is one of the processing chamber 124, 126, 128, and 130 without breaking vacuum where a conformal and/or nonconformal layer is deposited over the feature. For example, the conformal layer and/or nonconformal layer can include a tungsten layer that is deposited over the feature. The substrate may then be transferred to a third processing chamber which is one of the processing chambers 124, 126, 128, and 130 without breaking vacuum, where molybdenum is deposited on the conformal and/or nonconformal layer.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (for example, one transfer chamber) and/or more or fewer holding chambers (for example, no holding chambers) may be implemented as a transfer apparatus in a processing system.

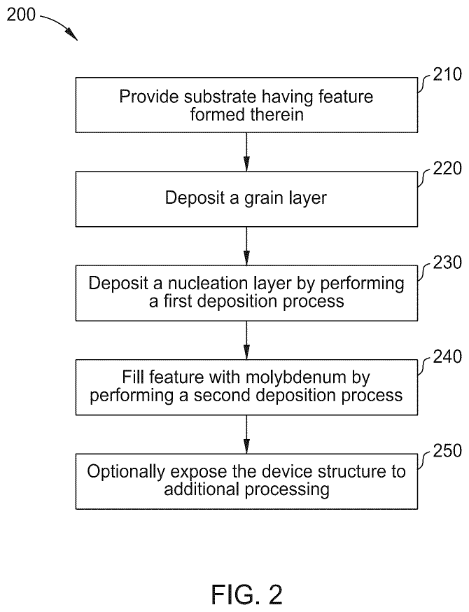

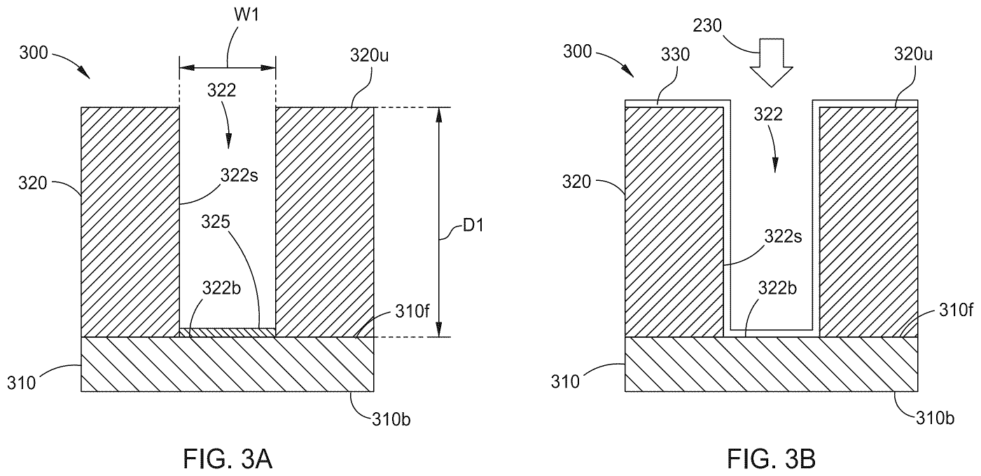

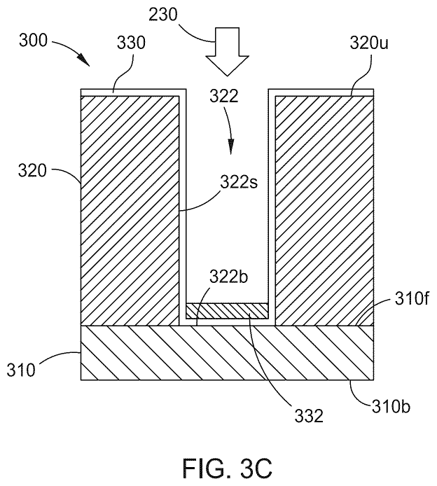

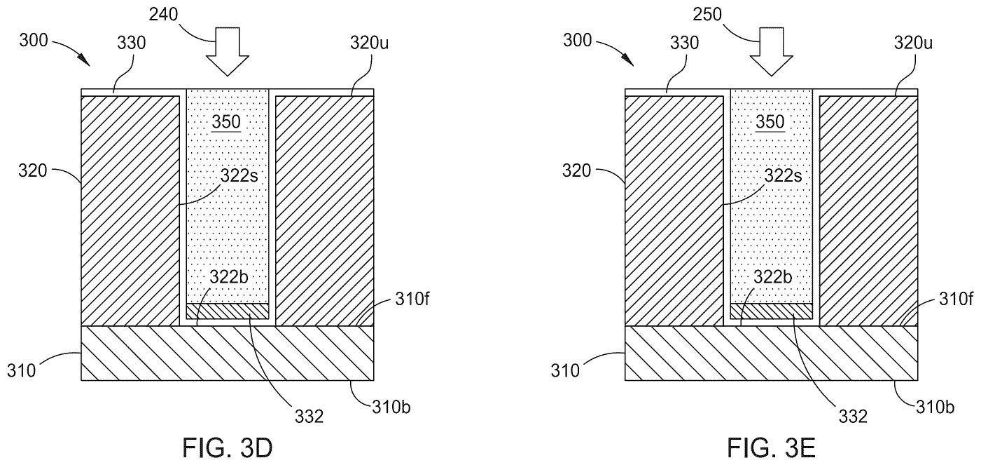

FIG. 2 illustrates a flow chart of a method 200 for manufacturing a device in accordance with one or more embodiments of the present disclosure. FIGS. 3A-3D illustrate views of various stages of manufacturing a device in accordance with one or more embodiments of the present disclosure. Although FIGS. 3A-3D are described in relation to the method 200, it will be appreciated that the structures disclosed in FIGS. 3A-3D are not limited to the method 200, but instead may stand alone as structures independent of the method 200. Similarly, although the method 200 is described in relation to FIGS. 3A-3D, it will be appreciated that the method 200 is not limited to the structures disclosed in FIGS. 3A-3D but instead may stand alone independent of the structures disclosed in FIGS. 3A-3D. It should be understood that FIGS. 3A-3D illustrate only partial schematic views of the device 300. The device 300 may contain any number of integrated circuit devices, or portions thereof, and additional materials having aspects as illustrated in the figures. It should also be noted that although the method 200 illustrated in FIG. 3A-3D is described sequentially, other process sequences that include one or more operations that have been omitted and/or added, and/or has been rearranged in another desirable order, fall within the scope of the embodiments of the disclosure provided herein.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

Referring to FIG. 2, at operation 210, a substrate 310 having a feature 322 formed therein is provided. FIG. 3A illustrates a cross-sectional view of the device 300 during intermediate stages of manufacturing corresponding to the operation 210. The device 300 includes the substrate 310 having one or more layers formed thereon, for example, the layer 320 as is shown in FIG. 3A, where the layer 320 can include a dielectric layer, e.g., a plurality of dielectric layers. The substrate 310 may be or include a bulk semiconductor substrate, a semiconductor-on-insulator (SOI) substrate, or the like, which may be doped (e.g., with a p-type dopant or an n-type dopant) or undoped. In some embodiments, the semiconductor material of the substrate 310 may include an elemental semiconductor, for example, such as silicon (Si) or germanium (Ge); a compound semiconductor including, for example, silicon carbide, gallium arsenide, gallium phosphide, indium phosphide, indium arsenide, and/or indium antimonide; an alloy semiconductor including, for example, SiGe, GaAsP, AllnAs, GalnAs, GalnP, and/or GalnAsP; a combination thereof, or the like. The substrate 310 may include additional materials, for example, silicide layers, metal silicide layers, metal layers, dielectric layers, etch stop layers, interlayer dielectrics, or a combination thereof.

The substrate 310 may further include integrated circuit devices (not shown). As one of ordinary skill in the art will recognize, a wide variety of integrated circuit devices such as transistors, diodes, capacitors, resistors, the like, or combinations thereof may be formed in and/or on the substrate 310 to generate the structural and functional requirements of the design for the resulting device 300.

The substrate 310 has a frontside 310f (also referred to as a front surface) and a backside 310b (also referred to as a back surface) opposite the frontside 310f. The layer 320 is formed over the frontside 310f of the substrate 310. The layer 320 may include multiple dielectric layers. The layer 320 includes an upper surface 320u or field region. In some embodiments, the layer 320 includes a dielectric material, such as a low k dielectric (SiCOH), silicon oxide, silicon dioxide (SiO₂), silicon nitride (Si₃N₄), silicon carbide (SiC), silicon oxynitride (SiON), aluminum oxide (Al₂O₃), aluminum nitride (AlN), a combination thereof, or multi-layers thereof. In some embodiments, the layer 320 consists essentially of silicon oxide. It is noted that the foregoing descriptors for example, silicon oxide, should not be interpreted to disclose any particular stoichiometric ratio. Accordingly, “silicon oxide” and the like will be understood by one skilled in the art as a material consisting essentially of silicon and oxygen without disclosing any specific stoichiometric ratio.

The layer 320 is patterned to form one or more feature(s) 322. The feature 322 may be a high aspect ratio (HAR) feature. In some embodiments, the feature 322 can be a via, a trench, a hole, or a combination thereof. For example, the feature 322 can be a via or include a via. In some embodiments, the feature 322 extends from the upper surface 320u of the layer 320 toward the frontside 310f of the substrate 310. The feature 322 includes sidewall surface(s) 322s and a bottom surface 322b extending between the sidewall surface(s) 322s. In some embodiments, the sidewall surface(s) 322s is tapered. The sidewall surface(s) 322s may be defined by the layer 320 and the bottom surface may be defined by the device substrate 310. The sidewall surface(s) 322s may be defined by a dielectric material and the bottom surface 322b may be defined by a dielectric material or other materials, for example, a silicide layer, a metal silicide layer, a semiconductor layer, an etch stop layer (ESL), or a metal layer.

In some embodiments, the sidewall surface(s) 322s is defined by the layer 320 and the bottom surface 322b may also be defined by the layer 320. In other embodiments, the sidewall surface(s) 322s is defined by the layer 320 and the bottom surface 322b is defined by a conductive material, for example, where the feature 322 is a via that is disposed over a lower interconnect layer or a bottom contact structure that is disposed over a metal plug or source/drain region. The conductive material may be formed of copper (Cu), cobalt (Co), molybdenum (Mo), tungsten (W), or ruthenium (Ru). The feature 322 has a first depth “D1” from the upper surface 320u to the bottom surface 322b and a width “W1” between the two sidewall surface(s) 322s. In some embodiments, the depth D1 is in a range of 2 nm to 200 nm, 3 nm to 200 nm, 5 nm to 100 nm, 2 nm to 100 nm, or 50 nm to 100 nm. In some embodiments, the width W1 is in a range of 10 nm to 100 nm, 10 nm to 20 nm, 10 nm to 50 nm, or 50 nm to 100 nm. In some embodiments, the feature 322 has an aspect ratio (D/W) in a range of 1 to 20, 5 to 20, 10 to 20, or 15 to 20.

In some embodiments, as shown in FIG. 3A, the device 300 may have a native oxide layer 325 or other contaminants formed on the sidewall surface(s) 322s, the bottom surface 322b, or both the sidewall surface(s) 322s and the bottom surface 322b of the feature 322. The device 300 may be exposed to atmosphere prior to or during processing, which may lead to the formation of the native oxide layer 325 on the surfaces of the feature and substrate. For example, if a vacuum break occurs prior to or during the method 200, the vacuum break can lead to the formation of native oxides. In addition, other processes performed prior to or during the method 200 may lead to the formation of additional contaminants or debris on the sidewall surface(s) 322s and the bottom surface 322b of the feature 322.

In some embodiments, the semiconductor device structure 300 is exposed to a pretreatment process. The pretreatment process can include one or more native oxide removal processes for removing the native oxide layer 325 (if present). The pretreatment process of operation 220 can include one more dry clean processes. Any suitable dry clean process may be performed. The dry clean process may include a plasma etch process, such as a two-part dry chemical clean process using NF₃ and NH₃, an H₂ and O₂ plasma etch process, an H₂ plasma etch process, or a combination thereof.

In some embodiments, which can be combined with other embodiments, the feature 322 is exposed to a dry clean process and/or a degas process prior to formation of one or more grain layers over a surface of the feature during operation 210. The dry clean process may be used to remove oxides from the surface of the feature 322. For example, if the feature 322 includes silicon, the Applied Materials SICONI® clean processes may be performed for removing oxide from the surfaces of the substrate and feature. The SICONI® clean process removes native oxide through a low-temperature, two-part dry chemical clean process using NF₃ and NH₃. The clean process may be performed in a processing chamber positioned on a cluster tool, for example, the processing system 100 (see FIG. 1). Exemplary pre-clean chambers in which the dry clean process of operation 210 may be performed include the SICONI® clean chamber and the Preclean XT chamber available from Applied Materials, Inc., of Santa Clara, Calif.

In one or more embodiments, which can be combined with other embodiments, the substrate and the feature may be exposed to a fluorine-containing precursor and a hydrogen-containing precursor in a two-part dry chemical clean process. In one or more embodiments which can be combined with other embodiments, the fluorine-containing precursor may include nitrogen trifluoride (NF₃), hydrogen fluoride (HF), diatomic fluorine (F₂), monatomic fluorine (F), fluorine-substituted hydrocarbons, combinations thereof, or the like. In one or more embodiments, which can be combined with other embodiments, the hydrogen-containing precursors may include atomic hydrogen (H), diatomic hydrogen (H₂), ammonia (NH₃), hydrocarbons, incompletely halogen-substituted hydrocarbons, combinations thereof, or the like.

In one or more embodiments, which can be combined with other embodiments, the first part of the two-part dry clean process includes using a remote plasma source to generate an etchant species, for example, ammonium fluoride (NHF₄), from the fluorine-containing precursor, for example, nitrogen trifluoride (NF₃), and the hydrogen-containing precursor, for example, ammonia (NH₃). By using a remote plasma source, damage to the substrate may be minimized. The etchant species may then be introduced into a pre-clean chamber, for example, the processing chamber 120, 122 depicted in FIG. 1, and condensed into a solid by-product on the surface of the substrate through a reaction with the native oxides present on the surface. The second part of the two-part dry clean process may then include an in-situ anneal to decompose the by-product using convection and radiation heating. The by-product then sublimates and may be removed from the surface of the feature via a flow of gas and pumped out of the pre-clean chamber.

In one or more embodiments which can be combined with other embodiments, the pre-treatment process is a plasma treatment process. The plasma treatment process can be an inductively coupled plasma (ICP) process or a capacitively coupled plasma (CCP) process. The plasma can be formed ex-situ in a remote plasma source (RPS). The plasma can be a direct plasma formed in-situ, for example, generated within a processing region. In one or more embodiments, which can be combined with other embodiments, the plasma treatment process includes exposing the device 300 to a plasma formed from a process gas including a hydrogen-containing gas. In one or more embodiments, which can be combined with other embodiments, the plasma treatment process includes exposing the substrate to a plasma formed from a process gas including both a hydrogen-containing gas and an oxygen-containing gas. In one example, the plasma treatment process includes exposing the feature 322 to an ICP formed from a process gas including a hydrogen-containing gas and an oxygen-containing gas. The process gas may further include an inert gas, for example, argon (Ar), helium (He), krypton (Kr), or a combination thereof. In one or more embodiments, which can be combined with other embodiments, the plasma treatment process includes exposing the feature to a plasma formed form a process gas including one or more of H₂, O₂, Ar, or a combination thereof. In one or more embodiments, which can be combined with other embodiments, the plasma treatment process can include exposing the feature to a hydrogen and oxygen plasma treatment. The hydrogen and oxygen plasma treatment can include a saturation conformal treatment, which includes a longer soak time and/or high reactant treatment, to provide for good subsequent metal-fill of the feature.

In one or more embodiments, which can be combined with other embodiments, the plasma treatment process is performed at temperatures of 400° C. or less. In one or more embodiments, which can be combined with other embodiments, the plasma treatment process includes supplying a processing gas including H2% greater than or equal to 90% of the total flow of hydrogen and oxygen.

Referring to FIG. 2, at operation 220, a grain layer is formed over the feature 322. FIG. 3B illustrates a cross-sectional view of the device 300 during intermediate stages of manufacturing corresponding to the operation 220. The grain layer 330 can control the grain size of the subsequently deposited molybdenum material. The grain layer 330 may be or include a metal layer, a metal, for example, tantalum, cobalt, titanium, tungsten, copper, ruthenium, the like, or a combination thereof. The grain layer 330 may be a conformal layer. The grain layer 330 may be a nonconformal layer. The grain layer 330 may be or include a metal, for example, tantalum, cobalt, titanium, tungsten, copper, ruthenium, the like, or a combination thereof. Although a single layer is depicted the grain layer 330 may include one or more additional conformal/nonconformal layers, for example, one or more of barrier, adhesion, and/or grain modification layers. The one or more additional conformal/nonconformal layers can include or be a nitride, for example, silicon nitride, carbon nitride, aluminum nitride, tantalum nitride, titanium nitride, tungsten nitride, the like, or a combination thereof, or a carbide, for example, tungsten carbide, aluminum carbide, the like, or a combination thereof. The grain layer 330 may be formed by any suitable deposition process such as ALD, CVD, PVD, or a hybrid ALD/CVD process. The grain layer 330 may be formed by a selective vapor deposition process, for example, a selective ALD, a selective CVD, or a selective hybrid ALD/CVD process. The grain layer 330 can be molybdenum-free. In one or more embodiments, which can be combined with other embodiments, the grain layer 330 has an initial thickness in a range from about 1 Å to about 100 Å, or in a range from about 10 Å to about 50 Å, or in a range from about 20 Å to about 50 Å, or in a range from about 10 Å to about 20 Å. The grain layer 330 may be or include a tungsten layer deposited via a PVD process. The grain layer 330 may be or include a tungsten layer deposited via a CVD process.

In one or more embodiments, which can be combined with other embodiments the grain layer 330 is formed over or directly on at least a portion of the at least one feature 322. In some embodiments, as is shown in FIG. 3B, the grain layer 330 may be formed over or directly on the sidewall surface(s) 322s and the bottom surface 322b of the feature 322 and over or on the upper surface 320u or field region of the layer 320. In other embodiments, the grain layer 330 is selectively formed over or on the bottom surface 322b of the feature 322 and the grain layer 330 either does not form on or minimally forms on the sidewall surface(s) 322s defined by the feature 322. In some embodiments, the grain layer 330 may be or include a tungsten layer. The tungsten layer may be formed directly on or over the surfaces of the feature 322. The grain layer 330 may be or include a tungsten layer having an initial thickness in a range from about 1 Å to about 100 Å, or in a range from about 20 Å to about 50 Å. In some embodiments, the grain layer 330 may be discontinuous along for example, the sidewall surface(s) 322s and/or the bottom surface 322b. Without being bound by theory, the grain layer 330 can be about the size of the critical dimension of the trench, thereby allowing for nucleation of a single grain in the trench.

In one embodiment, which can be combined with other embodiments, the grain layer 330 is formed on the bottom surface 322b by a selective deposition process. The bottom surface 322b may be defined by a metal layer, for example, such as in a metal contact structure. The bottom surface 322b may be defined by the layer 320, e.g., dielectric layer, for example, such as in a layer structure. The selective deposition process may be or include a vapor deposition process performed in a deposition chamber. The selective deposition process may be or include an ALD process, a CVD process, or a hybrid ALD/CVD process. The vapor deposition process may be or include introducing a tungsten halide precursor into the deposition chamber. The tungsten halide precursor may be or include tungsten hexachloride (WCl₆), tungsten hexachloride (WCl₅), or a combination thereof. The vapor deposition process may be or include introducing a cobalt precursor into the deposition chamber. The cobalt precursor may be or include dicobalt hexacarbonyl acetyl compounds, for example, dicobalt hexacarbonyl butylacetylene (CCTBA, CO₂(CO)₆[HC≡C(CH₃)₃)]. The vapor deposition process may be or further include introducing a reducing agent precursor gas into the deposition chamber. The reducing agent precursor gas is selected from molecular hydrogen (H₂), hydrogen atoms, a hydrogen plasma, hydrogen radicals, hydrogen excited species, or a combination thereof. In one example, the selective vapor deposition process includes introducing H₂ and WCl₅ into the deposition chamber. In another example, the selective vapor deposition process includes introducing H₂ and CCTBA into the deposition chamber.

Referring to FIG. 2, at operation 230, a nucleation layer 332 is deposited in the feature 322 using a first deposition process. FIG. 3C illustrates a cross-sectional view of the device 300 during intermediate stages of manufacturing corresponding to the operation 230. In some embodiments, the nucleation layer 332 can include a single layer of a molybdenum fill material 350. In some embodiments, the nucleation layer 332 can include a single crystal of a molybdenum fill material 350.

The first deposition process can include forming the nucleation layer 332 may by any suitable deposition process such as ALD, CVD, PVD, or a hybrid ALD/CVD process, as described below. Precursors used during the first deposition process may include molybdenum-containing precursors selected from molybdenum chlorides (e.g., MoClx, where x=2-6), molybdenum fluorides (MoF₆), molybdenum oxyhalides (e.g., MoO₂Cl₂, MoOCl₄). In some embodiments, the molybdenum chloride can be or include molybdenum (II) chloride, molybdenum (III) chloride, molybdenum (IV) chloride, molybdenum (V) chloride, molybdenum (IV) chloride, or a combination thereof. In particular embodiments, the molybdenum chloride precursor can be or include molybdenum (V) chloride that is molybdenum pentachloride (MoCl₅). Suitable examples of the metal containing precursor include Mo(NMe₂)₄, MoCl₅, MoF₆, tetramethylheptane-3,5-dionato (Mo(thd)₃), Mo(CO)₆, and the like.

For example, the nucleation layer 332 can be deposited using a CVD process including concurrently flowing (co-flowing) a molybdenum-containing precursor gas, a reducing agent, and optionally a carrier gas into a processing region and exposing the device 300 thereto. The molybdenum-containing precursor and the reducing agent used for the molybdenum-fill CVD process may include any combination of the molybdenum-containing precursors and reducing agents described herein. In particular embodiments, the molybdenum-containing precursor includes MoCl₅, and the reducing agent includes hydrogen gas. In some embodiments, the nucleation layer 332 forms a monoatomic layer and/or single crystal of molybdenum in the feature 322.

In some embodiments, the first deposition process includes flowing the molybdenum-containing precursor into the processing region at a flow rate in a range from about 0.01 sccm to about 2 sccm, e.g., about 0.01 sccm to about 1.5 sccm, about 0.1 sccm to about 1.0 sccm, or about 0.2 sccm to about 0.6 sccm. The reducing agent is flowed into the processing region at a flow rate of about 1,000 sccm to about 100,000 sccm, e.g., about 1,000 sccm to about 80,000 sccm, about 5,000 sccm to about 50,000 sccm, or about 20,000 sccm to about 40,000 sccm. In some embodiments, the molybdenum-containing precursor and the reducing agent are allowed into the processing region at a flow rate ratio of about 1×10⁻⁸ to 2×10⁻³ of molybdenum-containing precursor to reducing agent. The carrier gas may be flowed into the processing region at a flow rate in a range from about 10 sccm to about 5000 sccm, or more than about 50 sccm, or less than about 1000 sccm, or in a range from about 100 sccm to about 900 sccm. Without being bound by theory, a flow rate ratio of about 1×10⁻⁸ to 2×10⁻³ of molybdenum-containing precursor to reducing agent can prevent molybdenum etching during deposition, thereby reducing an incubation delay for filling a feature with a molybdenum gap fill material. Moreover, a flow rate ratio of about 1×10⁻⁸ to 2×10⁻³ of molybdenum-containing precursor to reducing agent can increase density of the molybdenum gap fill material by reducing the formation of byproducts forming in the nucleation layer.

In some embodiments, the nucleation layer CVD process conditions of operation 230 can include heating the substrate at a temperature of about 250° C. to about 450° C., e.g., about 300° C. to about 450° C., about 350° C. to about 450° C., or about 400° C. to about 450° C. During the CVD process, the processing region may be maintained at a pressure of less than about 500 Torr, less than about 600 Torr, less than about 500 Torr, less than about 400 Torr, or in a range from about 1 Torr to about 500 Torr, such as in a range from about 1 Torr to about 450 Torr, or in a range from about 1 Torr to about 400 Torr, or for example, in a range from about 1 Torr and about 300 Torr.

In some embodiments, the molybdenum-containing precursor and the reducing agent are each flowed into the processing region for a duration of between about 0.1 seconds and about 10 seconds, such as between about 0.5 seconds and about 5 seconds. The processing region may be purged between of the alternative flow of the molybdenum-containing precursor and the reducing agent exposures by flowing an inert purge gas, such as argon (Ar) or hydrogen, into the processing region for a duration in a range from about 0.1 seconds to about 10 seconds, such as in a range from about 0.5 seconds to about 5 seconds.

In some embodiments, the nucleation layer 332 is deposited using a pulsed CVD method that includes repeating cycles of alternately exposing the device 300 to a flow of either molybdenum-containing precursor gas or a reducing gas while concurrently pulsing either the molybdenum-containing precursor gas or the reducing gas, whichever is not used for the continuous flow. For example, the pulsed CVD method can include flowing the reducing gas, while pulsing the molybdenum-containing precursor gas. As a further example, the pulsed CVD method can include flowing the molybdenum-containing precursor gas, while pulsing the reducing gas. In some embodiments, the inert gas may be introduced between each pulse of the molybdenum-containing precursor gas or the reducing gas. In other embodiments, no inert gas may be introduced between each pulse of the molybdenum-containing precursor gas or the reducing gas.

Referring to FIG. 2, at operation 240, the feature 322 is filled with a molybdenum gap fill material by performing a second deposition process. FIG. 3D illustrates a cross-sectional view of the device 300 during intermediate stages of manufacturing corresponding to the operation 240. In some embodiments, the molybdenum fill material 350 can include the molybdenum material of the nucleation layer 332, thereby reducing and/or preventing byproducts or contaminants from forming in the feature 322.

The second deposition process can include filling the feature 322 with the molybdenum-fill material 350 by any suitable deposition process such as ALD, CVD, PVD, or a hybrid ALD/CVD process. Precursors used during the deposition process may include molybdenum-containing precursors selected from molybdenum chlorides (e.g., MoClx, where x=2-6), molybdenum fluorides (MoF₆), molybdenum oxyhalides (e.g., MoO₂Cl₂, MoOCl₄). In some embodiments, the molybdenum chloride can be or include molybdenum (II) chloride, molybdenum (III) chloride, molybdenum (IV) chloride, molybdenum (V) chloride, molybdenum (IV) chloride, or a combination thereof. In particular embodiments, the molybdenum chloride precursor can be or include molybdenum (V) chloride that is molybdenum pentachloride (MoCl₅). Suitable examples of the metal containing precursor include Mo(NMe₂)₄, MoCl₅, MoF₆, tetramethylheptane-3,5-dionato (Mo(thd)₃), Mo(CO)₆, and the like.

In some embodiments, molybdenum-fill material 350 is deposited using a CVD process including concurrently flowing (co-flowing) a molybdenum-containing precursor gas, a reducing agent, and optionally a carrier gas into a processing region and exposing the device 300 thereto. The molybdenum-containing precursor and the reducing agent used for the molybdenum-fill CVD process may include any combination of the molybdenum-containing precursors and reducing agents described herein. In particular embodiments, the molybdenum-containing precursor includes MoCl₅, and the reducing agent includes hydrogen gas. In some embodiments, the molybdenum-fill material 350 fills the remainder of the feature 322.

In some embodiments, the second deposition process includes flowing the molybdenum-containing precursor into the processing region at a flow rate in a range from about 2 sccm to about 5 sccm, e.g., about 2 sccm to about 4 sccm, about 2.5 sccm to about 4 sccm, or about 3 sccm to about 4 sccm. The reducing agent is flowed into the processing region at a flow rate of 1,000 sccm to about 100,000 sccm, e.g., about 1,000 sccm to about 80,000 sccm, about 5,000 sccm to about 50,000 sccm, or about 20,000 sccm to about 40,000 sccm. In some embodiments, the molybdenum-containing precursor and the reducing agent are allowed into the processing region at a flow rate ratio of about 2×10⁻⁵ to 5×10⁻³ of the molybdenum-containing precursors to the reducing agent, in which the ratio of the molybdenum-containing precursors and the reducing agent of the second deposition process is greater than the ratio of the molybdenum-containing precursors and the reducing agent of the first deposition process.

The carrier gas may be flowed into the processing region at a flow rate in a range from about 10 sccm to about 1200 sccm, or more than about 50 sccm, or less than about 1000 sccm, or in a range from about 100 sccm to about 900 sccm.

In some embodiments, the molybdenum-fill CVD process conditions of the second deposition process can include heating the substrate at a temperature of about 250° C. to about 450° C., e.g., about 300° C. to about 450° C., about 350° C. to about 450° C., or about 400° C. to about 450° C. During the CVD process, the processing region may be maintained at a pressure of less than about 500 Torr, less than about 600 Torr, less than about 500 Torr, less than about 400 Torr, or in a range from about 1 Torr to about 500 Torr, such as in a range from about 1 Torr to about 450 Torr, or in a range from about 1 Torr to about 400 Torr, or for example, in a range from about 1 Torr and about 300 Torr.

In some embodiments, the molybdenum-fill material 350 is deposited using a PVD process. In other embodiments, the molybdenum-fill material 350 is deposited at operation 240 using an atomic layer deposition (ALD) process. The molybdenum-fill ALD process includes repeating cycles of alternately exposing the semiconductor device structure 300 to a molybdenum-containing precursor gas and a reducing agent and purging the processing region between the alternating exposures.

In some embodiments, the second deposition process includes flowing the molybdenum-containing precursor and the reducing agent into the processing region for a duration of between about 0.1 seconds and about 10 seconds, such as between about 0.5 seconds and about 5 seconds. The processing region may be purged between the alternating exposures by flowing an inert purge gas, such as argon (Ar) or hydrogen, into the processing region for a duration in a range from about 0.1 seconds to about 10 seconds, such as in a range from about 0.5 seconds to about 5 seconds.

In other embodiments, the second deposition process may deposit the molybdenum-fill material 350 using a pulsed CVD method that includes repeating cycles of alternately exposing the device 300 to a flow of either molybdenum-containing precursor gas or a reducing gas while concurrently pulsing either the molybdenum-containing precursor gas or the reducing gas, whichever is not used for the continuous flow. For example, the pulsed CVD method can include flowing the reducing gas, while pulsing the molybdenum-containing precursor gas. As a further example, the pulsed CVD method can include flowing the molybdenum-containing precursor gas, while pulsing the reducing gas. In some embodiments, the inert gas may be introduced between each pulse of the molybdenum-containing precursor gas or the reducing gas. In other embodiments, no inert gas may be introduced between each pulse of the molybdenum-containing precursor gas or the reducing gas.

In some embodiments, a molybdenum precursor flow rate provided during the first deposition process and the second deposition process are each controlled so that a desired fill process result can be achieved. In some embodiments, a molybdenum flux ratio, e.g., a ratio of the flow rate of the molybdenum precursor provided in the first deposition process compared to the flow rate of the molybdenum precursor in the second deposition process is controlled during the performance of method 200. In one example, the molybdenum flux ratio may be controlled to a value from about 2×10⁻³ to about 0.9 from the first deposition process to the second deposition process. In some embodiments, a molybdenum flux ratio of from about 2×10⁻³ to about 0.9 can provide for increased density of the molybdenum gap fill material by reducing the formation of byproducts forming in the nucleation layer.

In some embodiments, the method 200 can include a third deposition process. The third deposition process can include flowing the molybdenum-containing precursor into the processing region at a flow rate in a range from about 5 sccm to about 10 sccm, e.g., about 5 sccm to about 9 sccm, about 6 sccm to about 8 sccm, or about 6 sccm to about 7 sccm. The third deposition process can include flowing the reducing agent into the processing region at a flow rate rate of about 1,000 sccm to about 100,000 sccm, e.g., about 1,000 sccm to about 80,000 sccm, about 5,000 sccm to about 50,000 sccm, or about 20,000 sccm to about 40,000 sccm. In some embodiments, third deposition process includes a flow rate ratio of the molybdenum-containing precursor to the reducing agent of about 5×10⁻⁵ to about 1×10⁻², in which the ratio of the molybdenum-containing precursors and the reducing agent of the third deposition process is greater than the ratio of the molybdenum-containing precursors and the reducing agent of the first deposition process or the second deposition process. Without being bound by theory, a ratio of the molybdenum-containing precursor to the reducing agent that is greater than the first deposition process or the second deposition process can increase the rate at which molybdenum gap fill material is deposited in the feature, thereby reducing the manufacturing costs and decreasing processing time for device production.

In some embodiments, the method 200 can include a fourth deposition process, fifth deposition process, sixth deposition process, seventh deposition process, eighth deposition process, ninth deposition process, or tenth deposition process to form a gradient of ratios of the molybdenum-containing precursor to the reducing agent per unit time. For example, the gradient of ratios may increase during operation 240 such that the rate of molybdenum gap fill material deposition increases as the feature becomes filled with the molybdenum gap fill material. Without being bound by theory, by implementing a gradient of ratios, where the gradient increases the ratio of the molybdenum-containing precursor to the reducing agent, an increase in the rate at which molybdenum gap fill material is deposited in the feature can occur, thereby reducing the manufacturing costs and decreasing processing time for device production

Referring to FIG. 2, optionally at operation 250, the device 300 is exposed to additional processing. FIG. 3E illustrates a cross-sectional view of the device 300 during intermediate stages of manufacturing corresponding to the operation 250. In some embodiments, a planarization process, for example a CMP process or an etchback process may be performed to remove excess portions or overburden of the molybdenum-fill material (if present). For example, as shown in FIG. 3E, portions of the molybdenum-fill material 350 and the grain layer 330 are planarized to expose the upper surface 320u of the layer 320. In some embodiments, an annealing process may be performed during operation 250.

### Examples

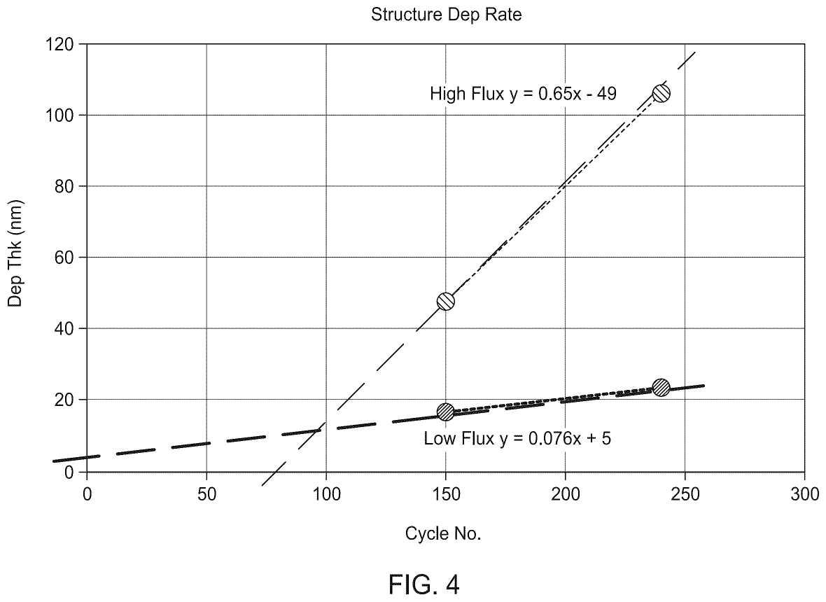

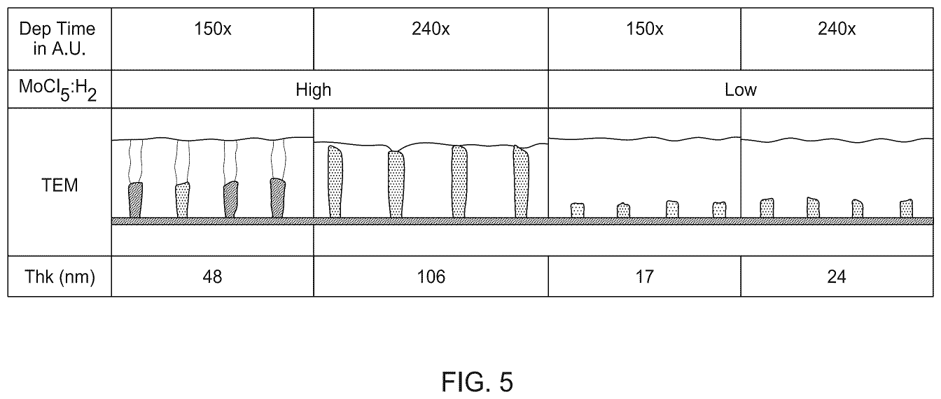

A first deposition process having a first molybdenum-containing precursor, e.g., MoCl₅, flow rate of about 0.05 sccm and a first reducing gas, e.g., H₂, flow rate of about 10000 sccm was compared to a second deposition process having a second molybdenum-containing precursor, e.g., MoCl₅, flow rate of about 1 sccm and a second reducing gas, e.g., H₂, flow rate of about 10,000 sccm. Each of the first deposition process and the second deposition process used pulsed CVD, where a first pulse of 1.0 s of the MoCl₅ was followed by a second pulse of 4.5 seconds of the H₂. The temperature of the substrate for each of the first deposition process and the second deposition process was 400° C. The first deposition process had no incubation delay, while the second deposition had a 75 cycle delay prior to growth of the molybdenum gap fill material in the feature, as shown in FIG. 4. Moreover, after a deposition time of 150 arbitrary units of the first deposition process the molybdenum gap fill material had a thickness of 17 nm, while after a deposition time of 150 arbitrary units of the second deposition process the molybdenum gap fill material had a thickness of 48 nm, as shown in FIG. 5. Additionally, after a deposition time of 240 arbitrary units of the first deposition process the molybdenum gap fill material had a thickness of 24 nm, while after a deposition time of 240 arbitrary units of the second deposition process the molybdenum gap fill material had a thickness of 106 nm, as shown in FIG. 5.

Overall, the present disclosure can reduce manufacturing costs of semiconductor devices, while still providing a dense molybdenum gap fill material. The first deposition process can reduce an incubation delay for forming the nucleation layer due to the lower flux utilized compared to conventional deposition processes. Moreover, the first deposition process can reduce the total amount of etching of the gap fill material due to the lower flux compared to conventional deposition processes, thereby reducing byproducts from forming in the nucleation layer and/or the gap fill material. Additionally, the second deposition process, having a higher flux compared to the first deposition process, can reduce the total manufacturing time without reducing gap fill density, thereby reducing manufacturing costs. However, the present disclosure does not necessitate that all the advantageous features and all the advantages need to be incorporated into every embodiment of the present disclosure.

Embodiments and all of the functional operations described in this specification can be implemented in digital electronic circuitry, or in computer software, firmware, or hardware, including the structural means disclosed in this specification and structural equivalents thereof, or in combinations of them. Embodiments described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises” and grammatical equivalents thereof, for example, “including” and “having,” are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility). In addition some of the operations described in the methods 200A-B may be omitted unless stated otherwise.

When introducing elements of the present disclosure or exemplary aspects or embodiment(s) thereof, the articles “a,” “an,” “the” and “said” are intended to mean that there are one or more of the elements.

While the foregoing is directed to embodiments of the present disclosure, other and further embodiments of the disclosure may be devised without departing from the basic scope thereof, and the scope thereof is determined by the claims that follow.

1. A method of processing a semiconductor device substrate, comprising:
depositing a nucleation layer on a surface of a feature formed in a surface of a substrate by use of a first deposition process, the first deposition process comprising flowing a molybdenum-containing precursor and a reducing agent precursor gas into a processing chamber at a first flow rate ratio of about 1×10⁻⁸ to about 2×10⁻³ of molybdenum-containing precursor to reducing agent; and
filling at least a portion of the feature with a molybdenum gap fill material by exposing the deposited nucleation layer to a second deposition process, the second deposition process comprising flowing the molybdenum-containing precursor and the reducing agent precursor gas into a processing chamber at a second flow rate ratio of about 2×10⁻⁵ to about 1×10⁻² of molybdenum-containing precursor to reducing agent, wherein the second flow rate ratio is greater than the first flow rate ratio.

2. The method of claim 1, further comprising:
depositing a grain layer over at least a portion of the feature before depositing the nucleation layer,
wherein the grain layer comprises a metal different from molybdenum.

3. The method of claim 2, wherein depositing the grain layer comprises depositing tungsten by use of a physical vapor deposition (PVD) process.

4. The method of claim 1, wherein the molybdenum-containing precursor comprises molybdenum chloride precursor, a molybdenum oxyhalide precursor, or a combination thereof.

5. The method of claim 4, wherein the reducing agent precursor gas is selected from molecular hydrogen (H₂), hydrogen atoms, a hydrogen plasma, hydrogen radicals, hydrogen excited species or a combination thereof.

6. The method of claim 5, wherein the first deposition process and the second deposition process comprises molybdenum pentachloride and molecular hydrogen.

7. The method of claim 1, wherein the first deposition process and the second deposition process comprises a chemical vapor deposition process or a pulsed chemical vapor deposition.

8. The method of claim 1, wherein the first deposition process and the second deposition process are performed at a temperature of about 250° C. to about 450° C.

9. The method of claim 8, wherein the first deposition process and the second deposition process are performed at a pressure of about 1 Torr to about 100 Torr.

10. A method for processing a semiconductor device structure, comprising:
depositing a grain layer comprising tungsten over at least a portion of a feature formed in a surface of a substrate by use of a physical vapor deposition (PVD) process, wherein the PVD process is performed in a first processing region of a first processing chamber;
transferring the substrate from the first processing region of the first processing chamber to a second processing region of a second processing chamber without breaking vacuum; and
depositing a nucleation layer on the grain layer by exposing the feature to a first deposition process, the first deposition process comprising flowing a molybdenum-containing precursor and a reducing agent precursor gas into a processing chamber at a first flow rate ratio of about 1×10⁻⁸ to about 2×10⁻³ of molybdenum-containing precursor to reducing agent; and
filling the feature with a molybdenum gap fill material by exposing the feature to a second deposition process, the second deposition process comprising flowing the molybdenum-containing precursor and the reducing agent precursor gas into a processing chamber at a second flow rate ratio of about 2×10⁻⁵ to about 1×10⁻² of molybdenum-containing precursor to reducing agent, wherein the second flow rate ratio is greater than the first flow rate ratio.

11. The method of claim 10, wherein the molybdenum-containing precursor comprises molybdenum chloride precursor, a molybdenum oxyhalide precursor, or a combination thereof.

12. The method of claim 11, wherein the reducing agent precursor gas is selected from molecular hydrogen (H₂), hydrogen atoms, a hydrogen plasma, hydrogen radicals, hydrogen excited species or a combination thereof.

13. The method of claim 12, wherein the first deposition process and the second deposition process comprises molybdenum pentachloride and molecular hydrogen.

14. The method of claim 10, wherein the first deposition process and the second deposition process comprises a chemical vapor deposition process or a pulsed chemical vapor deposition.

15. The method of claim 10, wherein the first deposition process and the second deposition process are performed at a temperature of about 250° C. to about 450° C.

16. The method of claim 10, wherein the first deposition process and the second deposition process are performed at a pressure of about 1 Torr to about 100 Torr.

17. A method for processing a semiconductor device substrate, comprising:
depositing a nucleation layer on a surface of a feature formed in a surface of a substrate by use of a first deposition process, the first deposition process comprising flowing a molybdenum-containing precursor into a processing chamber at a first flow rate; and
filling at least a portion of the feature with a molybdenum gap fill material by exposing the deposited nucleation layer feature to a second deposition process, the second deposition process comprising flowing the molybdenum-containing precursor at a second flow rate,
wherein a ratio of the first flow rate to the second flow rate is from about 2×10⁻⁵ to about 1×10⁻² of molybdenum-containing precursor to reducing agent.

18. The method of claim 17, wherein the first flow rate is between about 0.01 sccm to about 2 sccm.

19. The method of claim 18, further comprising flowing a reducing agent into the processing chamber during the first deposition process at a flow rate of between about 1,000 sccm to 100,000 sccm.

20. The method of claim 17, wherein the second flow rate is between about 2 sccm to 5 sccm.
